(19) United States
(12) Patent Application Publication
(10) Pub. No.: US 2018/0235075 A1
(43) Pub. Date: Aug. 16, 2018

(54) SHIELDING FOR SEMICONDUCTOR OPTOELECTRONIC DEVICES AND PACKAGES

(71) Applicant: Intel Corporation, Santa Clara, CA (US)

(72) Inventors: Taylor Gaines, Chandler, AZ (US); Anna M. Prakash, Chandler, AZ (US); Ziv Belman, Yokneam Ilit (IL); Baruch Schiffmann, Shoham (IL); Arnon Hirshberg, Misgav (IL); Ron Wittenberg, Haifa (IL); Vladimir Malamud, Hedera (IL)

(21) Appl. No.: 15/434,919

(22) Filed: Feb. 16, 2017

(51) Int. Cl. H05K 1/02; H05K 3/22; H05K 1/18

(52) U.S. Cl. CPC H05K 1/0216; H05K 3/22; H05K 1/18; H05K 2201/10083; H05K 2201/10159; H05K 2201/10121; H05K 2201/10106; H05K 2201/10151; H05K 2201/10098

(57) ABSTRACT

Semiconductor packages may include different portions associated one or more electronic components of the semiconductor package where electromagnetic (for example, radio-frequency, RF) shielding at predetermined frequencies ranges may be needed. Accordingly, in an embodiment, compartmental shielding can be used in the areas between the electronic components on the semiconductor package to provide RF shielding to the electronic components on the semiconductor package or to other electronic components in proximity to the electronic components on the semiconductor package. Further, in another embodiment, conformal coating shielding can be used to provide RF shielding to provide RF shielding to the electronic components on the semiconductor package or to other electronic components in proximity to the electronic components on the semiconductor package.

### TECHNICAL FIELD

This disclosure generally relates to shielding, and more particularly to shielding for semiconductor devices and packages.

### BACKGROUND

Electromagnetic interference (EMI) can refer to electronic disturbances generated by an external source that affects an electrical circuit, for example, by electromagnetic induction, electrostatic coupling, and/or conduction. For example, electromagnetic interference at a frequency 2.4 GHz can be caused by 802.11b and 802.11g wireless devices, Bluetooth devices, baby monitors and cordless telephones, video senders, and microwave ovens. The electronic disturbance may degrade the performance of the electrical circuit.

### BRIEF DESCRIPTION OF THE FIGURES

Reference will now be made to the accompanying drawings, which are not necessarily drawn to scale, and wherein:

FIG. 1 shows example top and side views of a portion of a semiconductor package having several electronic components that can be shielded using compartmental shielding and conformal coating shielding, in accordance to one or more example embodiments of the disclosure;

FIG. 2A shows a first diagram of an example conformal coating shield that can be deposited on an example surface of an electronic component and/or a surface of a molding compound (not shown) deposited on an electronic component, in accordance with example embodiments of the disclosure. FIG. 2B further shows a second diagram of an example compartmental shield that can be deposited on an example surface of a substrate (for example, a printed circuit board (PCB), not shown) and/or a surface of a molding compound (not shown) deposited on an electronic component or a substrate, between at least two electronic components, in accordance with example embodiments of the disclosure;

FIG. 3 shows a photograph of an example fabricated conformal coating shield deposited on a molding compound, in accordance with example embodiments of the disclosure;

FIG. 4 shows a photograph of an example fabricated compartmental shield deposited in a trench between two electronic components, in accordance with example embodiments of the disclosure;

FIG. 5 shows an example processing flow diagram for the fabrication of the compartmental and/or conformal coating shields, in accordance with example embodiments of the disclosure; and

FIG. 6 shows an example of a system, in accordance with example embodiments of the disclosure.

### DETAILED DESCRIPTION

Embodiments of the disclosure are described more fully hereinafter with reference to the accompanying drawings, in which example embodiments of the disclosure are shown. This disclosure may, however, be embodied in many different forms and should not be construed as limited to the example embodiments set forth herein; rather, these embodiments are provided so that this disclosure will be thorough and complete, and will fully convey the scope of the disclosure to those skilled in the art. Like numbers refer to like, but not necessarily the same or identical, elements throughout.

The following embodiments are described in sufficient detail to enable at least those skilled in the art to understand and use the disclosure. It is to be understood that other embodiments would be evident based on the present disclosure and that process, mechanical, material, dimensional, process equipment, and parametric changes may be made without departing from the scope of the present disclosure.

In the following description, numerous specific details are given to provide a thorough understanding of various embodiments of the disclosure. However, it will be apparent that the disclosure may be practiced without these specific details. In order to avoid obscuring the present disclosure, some well-known system configurations and process steps may not be disclosed in full detail. Likewise, the drawings showing embodiments of the disclosure are semi-diagrammatic and not to scale and, particularly, some of the dimensions are for the clarity of presentation and may be exaggerated in the drawings. In addition, where multiple embodiments are disclosed and described as having some features in common, for clarity and ease of illustration, description, and comprehension thereof, similar and like features will ordinarily be described with like reference numerals even if the features are not identical.

The term “horizontal” as used herein may be defined as a direction parallel to a plane or surface (for example, surface of a substrate), regardless of its orientation. The term “vertical,” as used herein, may refer to a direction orthogonal to the horizontal direction as just described. Terms, such as “on,” “above,” “below,” “bottom,” “top,” “side” (as in “sidewall”), “higher,” “lower,” “upper,” “over,” and “under,” may be referenced with respect to a horizontal plane, where the horizontal plane can include an x-y plane, a x-z plane, or a y-z plane, as the case may be. The term “processing” as used herein includes deposition of material or photoresist, patterning, exposure, development, etching, cleaning, ablating, polishing, and/or removal of the material or photoresist as required in formation a described structure.

In one embodiment, the shielding systems, methods, and apparatus disclosed herein can be used in connection with electronic components, for example, electronic components on a semiconductor package. In one embodiment, the electronic components can include mobile camera modules. In another embodiment, the systems, methods, and apparatus disclosed herein can be used in connection with semiconductor packages, for example, optoelectronics packages. Other non-limiting examples of electronic components that can be used in connection with the disclosure include Central Processing Units (CPUs), logic chips, memory chips, LTE chips, Bluetooth chips, Wi-Fi chips, photodetectors, and/or sensors.

In one embodiment, semiconductor packages may include different portions associated one or more electronic components of the semiconductor package where electromagnetic (for example, radio-frequency, RF) shielding at predetermined frequencies ranges may be needed. In one embodiment, a can (for example, a metallic can) can be used to enclose various portions of the semiconductor package to provide shielding for one or more electronic components (for example, one or more detectors and/or optoelectronic packages and/or devices) on the semiconductor package.

In one embodiment, one or more electronic components on a semiconductor package may emit electromagnetic radiation at various frequencies. For example, low frequency radiation (below approximately 1 GHz) can be emitted by switches, motors, power supplies, and transformers. As another example, higher frequency (for example, approximately 1 GHz to approximately 10 GHz frequencies) radiation can be emitted by components including CPUs or logic chips, memory chips, Long-Term Evolution (LTE) chips, Bluetooth chips, and/or Wi-Fi chips. Such radiation may need to be attenuated by the shielding systems, methods, and apparatus disclosed herein, in order to reduce interference with electronic components that are exposed to the radiation.

Accordingly, in an embodiment, compartmental shielding can be used in the areas between the electronic components on the semiconductor package to provide RF shielding to the electronic components on the semiconductor package or to other electronic components in proximity to the electronic components on the semiconductor package. Further, in another embodiment, conformal coating shielding can be used to provide RF shielding to provide RF shielding to the electronic components on the semiconductor package or to other electronic components in proximity to the electronic components on the semiconductor package.

In one embodiment, the conformal coating shielding can also be used to provide shielding for the other portions of semiconductor package that may not be immediately proximate to the one or more electronic components to be shielded. For example, conformal coating shielding can be used to protect portions of the semiconductor package having second electronic components that have a larger distance to the electronic components. Alternatively or additionally, conformal coating shielding can be used to protect second electronic components on an adjacent board proximate to the board housing the electronic components on the semiconductor package.

In one embodiment, various materials including spray prints, conductive paste, inks (for example, sinterable silver-based materials), epoxy material (for example, epoxy materials filled with silver and/or other metal particles) can be used to provide the compartmental and/or the conformal coating shielding.

In one embodiment, the materials can include materials that can be sputtered for providing the compartmental and/or the conformal coating shielding. For example, a multilayer compartmental and/or the conformal coating shield can be sputtered where titanium can serve as a seed layer, copper can serve as a shielding layer, and stainless steel layer can serve as the cover layer. Alternatively or additionally, CuNiFeZn and/or other ferrites can be used as a shielding layer for lower-frequency applications.

In one embodiment, metals can be plated (using various plating chemistries) as the shielding layer for providing the compartmental and/or the conformal coating shielding. In one embodiment, sinterable nanoparticles (for example, silver, copper, and other metal nanoparticles) can be used as the shielding layer. In one embodiment, non-sinterable pastes and/or inks (for example, non-sinterable pastes and/or inks containing metals such as Ag, Cu, Ni, Fe) in an epoxy, acrylic, or other polymer formulation can be used for the shielding layer. In one embodiment, intermetallic compound (IMC) forming materials (such as SnBiCu pastes), and/or conductive particles (such as fibers, flakes, nanoparticles, graphite, and the like) can be used for the shielding layer.

In various embodiments a variety of techniques can be used to deposit the shielding material for providing the compartmental and/or the conformal coating shielding. The techniques can include sputtering techniques, spraying techniques (including atomization, electrospray, and/or ultrasonic spraying techniques) to deposit the shielding material. In another embodiment, plating (including, for example, electrolytic and electroless plating), printing (including, for example, vacuum printing and/or conventional printing), and/or dispensing techniques (including, for example, Auger and/or jet dispensing) techniques can be used.

In one embodiment, the material(s) used for conformal coating shielding and/or compartmental shielding can be selected to provide shielding at a frequency range of approximately 2.4 to approximately 5 GHz. In another embodiment, the material(s) used for conformal coating shielding and/or compartmental shielding can be selected to provide shielding at comparatively lower frequency ranges (for example, shielding from radiation having a frequency in the MHz range). For example, ferromagnetic materials can be used to provide the shielding at the comparatively lower frequency ranges.

In one embodiment, for comparatively lower frequency shielding, the shielding material for conformal coating shielding and/or compartmental shielding can be selected based at least in part on the shielding material's magnetic permeability. In one embodiment, iron can be used for the shielding material to provide shielding at the comparatively lower frequency ranges. In another embodiment, the resistivity of the shielding material may not as important of a consideration as the magnetic permeability in the shielding properties of the shielding layer and/or multilayer for comparatively lower frequency applications. In one embodiment, the lower-frequency conformal coating shielding and/or compartmental shielding can reduce RF interference from power lines or similar structures in the environment of the shielded electronic components and/or the shielded semiconductor package.

In one embodiment, one advantage of the disclosed systems, methods, and apparatus can be in providing low-cost RF shielding that may not add any additional tools for fabrication and customization for specific electronic components and/or semiconductor packages. For example, RF shielding using metallic cans may take up valuable on-board real-estate on a semiconductor package. As such, an advantage of the disclosed systems, methods, and apparatus can be the reduction in the need for the use of such metallic cans.

In various embodiments, sprayable and/or dispensable shielding materials can be used as described herein to provide shielding to one or more electronic components and semiconductor packages. In one embodiment, such shielding materials may use far less on-board real-estate. For example, approximately 5 microns of shielding material comprising sprayable and/or dispensable materials may be used to provide RF shielding that may be equivalent to using an approximately 100 microns metallic can to provide the same level of RF shielding. Further, metallic cans and similar physical shielding structures (for example, Faraday cages, meshes, and the like) may need separate tooling procedures to be performed prior to fabrication and application and may need to be specifically designed for a given semiconductor package and/or electronic component. Another advantage of the disclosed systems, methods, and apparatus can be in permitting a single machine for dispensing the shielding materials using predetermined workflows and/or recipes that can be quickly adjusted for different semiconductor packages and/or electronic components, for example, without the need for re-tooling.

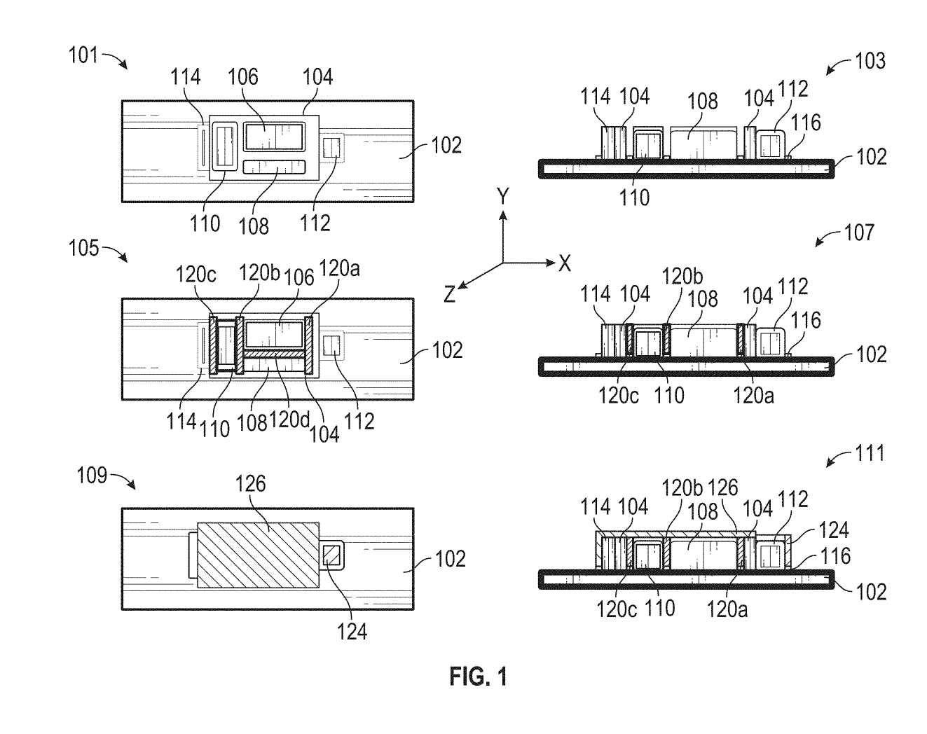

FIG. 1 shows example top and side views of a portion of a semiconductor package having several electronic components that can be shielded using compartmental shielding and/or conformal coating shielding, in accordance to one or more example embodiments of the disclosure. In one embodiment, the electronic components can be separated by a predetermined space on the order of several microns. In one embodiment, a metallic can may not be able to fit into such a small spacing or form factor. As such, the disclosed systems, methods, and apparatus can permit the use of smaller packages with tighter spacing between electronic components.

In particular, diagram 101 shows a portion of a semiconductor package from a top view, further showing several electronic components (for example the electronic components 106, 108, and 110) mounted on a PCB board 102. The portion of the semiconductor package shown in diagram 101 can further include a molding compound 104, a first electronic component (for example, a photo diode) 106, a second electronic component (for example, an memory device) 108, a third electronic component (for example, an capacitor or an inductor) 110, a first connection port 112, and/or a second connection port 114. In an embodiment, the electronic components (for example the electronic components 106, 108, and 110) on the portion of the semiconductor package shown in diagram 101 have not had the application of any shielding (compartmental shielding and/or conformal coating shielding).

In one embodiment, while only a few electronic components are shown in diagram 101, there may be approximately hundreds of electrical components on a given semiconductor package (for example, a semiconductor package including an optoelectronic device), but not every electronic component may need to be shielded. For example, there may be a predetermined number of electronic components (for example, three to four electronic components) that may need to be shielded from electromagnetic radiation at predetermined frequencies. In one embodiment, the semiconductor (for example, optoelectronic) package used in connection with this disclosure may be approximately 70 cm by approximately 3 cm in area.

In one embodiment, depending on what frequency the electronic components may need to be to be shielded, the type of shielding material applied (for example, sprayed, coated, dispensed, printed, and the like) on the electronic components and/or semiconductor package can vary. For example, the shielding material can include a nickel and/or iron-based material that can be deposited using different techniques, including spraying, printing, and/or coating techniques, to be discussed further below.

In one embodiment, diagram 103 further shows the portion of a semiconductor package shown in diagram 101 from a side view. In particular diagram 103 shows some of the same electronic components (for example the electronic components 108 and 110) on the PCB board 102, similar to that in diagram 101 but shown from a side view perspective. For example, diagram 103 shows the PCB board 102, the molding compound 104, and the side view of the second electronic device 108. (In one embodiment, the side view of the first electronic component 106 is blocked by the side view of the second electric component 108 in this particular orientation). In one embodiment, diagram 103 further shows the third electronic component 110, the first connection port 112, and the second connection port 114. Further, ground pads 116 are also present and shown on the diagram 103. These ground pads 116 can be used in connection with the compartmental shield and the conformal coating shield, discussed below.

In an embodiment diagram 105 shows the portion of a semiconductor package (as previously shown and described in connection with diagrams 101 and 103), after partial shielding with one or more compartmental shields in accordance with embodiments described herein. Again, the portion of a semiconductor package shown in diagram 105 is formed on a PCB board 102. The portion of a semiconductor package 105 can further include a molding compound 104, a first electronic component (for example, a photo diode) 106, a second electronic component (for example, a memory device) 108, a third electronic component (for example, a capacitor or an inductor) 110, a first connection port 112, and/or a second connection port 114.

In an embodiment, the electronic components (for example the electronic components 106, 108, and 110) on the portion of the semiconductor package shown in diagram 105 have had the application of compartmental shielding 120a-120c. For example, a first compartmental shield 120a is shown between the first electronic component 104 the second electronic component 108 and the first connection port 112. Additionally a second compartmental shield 120b is shown between the first electronic component 106, the second electronic component 108, and the third electronic component 110. Further shown is a third compartmental shield 120c between the third electronic component 110 and the second connection port 114. In one embodiment, there can be additional compartmental shields similar to, but not necessarily identical to, the compartment shields 120a-120c shown in diagram 105. For example, there may be additional shields between electronic components (for example compartmental shield 120d between the first electronic component 106 and the second electronic component 108) or any other position on the electronic device 101 (not shown). In one embodiment, the compartmental shields (such as compartmental shields 120a-120d) shown in connection with diagram 105 are only exemplary compartmental shields.

In an embodiment diagram 107 shows a side view of the electronic device shown in diagram 105 with the actual partial shielding with compartmental shields shown and described in connection with diagram 105. In particular, diagram 107 further shows the portion of a semiconductor package shown in diagrams 101 and 105 from a side view. In particular diagram 107 shows some of the same electronic components (for example the electronic components 108 and 110) on the PCB board 102, similar to that in diagram 105 but shown from a side view perspective. For example, diagram 107 shows the PCB board 102, the molding compound 104, and the side view of the second electronic device 108. (In one embodiment, the side view of the first electronic component 106 is blocked by the side view of the second electric component 108 in this particular orientation). In one embodiment, diagram 107 further shows the third electronic component 110, the first connection port 112, and the second connection port 114. Further, ground pads 116 are also shown. These ground pads 116 can be used in connection with the compartmental shield and the conformal coating shield.

Further shown in diagram 107 is the compartmental shields 120a-120c, shown in the side view. For example, a first compartmental shield 120a is shown between the first electronic component 104 and the first connection port 112. Additionally a second compartmental shield 120b is shown between the first electronic component 106 and the third electronic component 110. Further shown is a third compartmental shield 120c between the third electronic component 110 and the second connection port 114. In one embodiment, there can be additional compartmental shields similar to, but not necessarily identical to, the compartment shields 120a-120c shown in diagram 107. For example, there may be additional shields between electronic components (for example a compartmental shield between the first electronic component 106 and the second electronic component 108, not shown), or on any other position on the portion of the semiconductor package of diagram 107 (not shown). In one embodiment, the compartmental shields (such as compartmental shields 120a-120c) shown in connection with diagram 107 are only exemplary compartmental shields.

In an embodiment, diagram 109 shows the portion of the semiconductor package (for example, the semiconductor package as shown and described in connection with diagrams 101, 103, 105 and 107) after being shielded with both compartmental shielding and conformal coating shielding in accordance with embodiments described herein. In particular, the portion of the semiconductor package shown in diagram 109 including PCB 102 is now shown to have an additional conformal coating shield 126 both on the various electronic components (for example the electronic components 106, 108, and 110 variously shown and described in connection with diagrams 101, 103, 105 and 107) and on the connection ports (for example ports 112 and 114 shown and describe in connection with diagrams 101, 103, 105 and 107). In one embodiment, the conformal coating shielding 126 can include portions of the PCB 102 and/or other electronic components (not shown) that reside elsewhere on the semiconductor package.

In an embodiment, diagram 111 shows a side view of the electronic device shown and described in connection with diagrams 101, 103, 105, 107, and 109 after being completely shield with both compartmental shielding (as shown by 120a-120c in diagram 105 and 107) and conformal coating shielding 126. In particular, a conformal coating shield 126 is shown to cover the electronic components (for example the second electronic components 108, the third electronic component 110) on the semiconductor package. In one embodiment, the first electronic component (not shown in this side view) can also be covered by the conformal coating shielding 126. Further shown in the portion of the semiconductor package shown in diagram 111 is an example of the side wall coverage 124 of the conformal coating shielding 126. In this example the conformal coating shield 126 provides side wall coverage 124 to the first connection port 112 or second connection port 114.

In one embodiment, the top of the electronic components and/or semiconductor package can be shielded using a conformal coating shield. In another embodiment, the conformal coating shield can be sprayed and/or sputtered (for example, for metal conformal coating shields). In one embodiment, the conformal coating shield can be applied using an atomization technique, ultra-sonic spray technique, and/or an electric spray technique.

In one embodiment, the materials used for the conformal coating shielding layer can include sinterable metal samples and/or non-sinterable metal samples that can be suspended in solution or a polymer. In one embodiment, one or more trenches between electronic components on the semiconductor package can be filled using a printing and/or dispensing technique or dispensed into the trench.

In one embodiment, the conformal coating shielding technique can be used in connection with high-frequency switching electronic components, such as memory, Bluetooth, Wi-Fi, and/or LTE modules. Such high-frequency switching electronic components may need to be shielded to reduce interference with the optoelectronic package and/or device(s) on a semiconductor package including a camera.

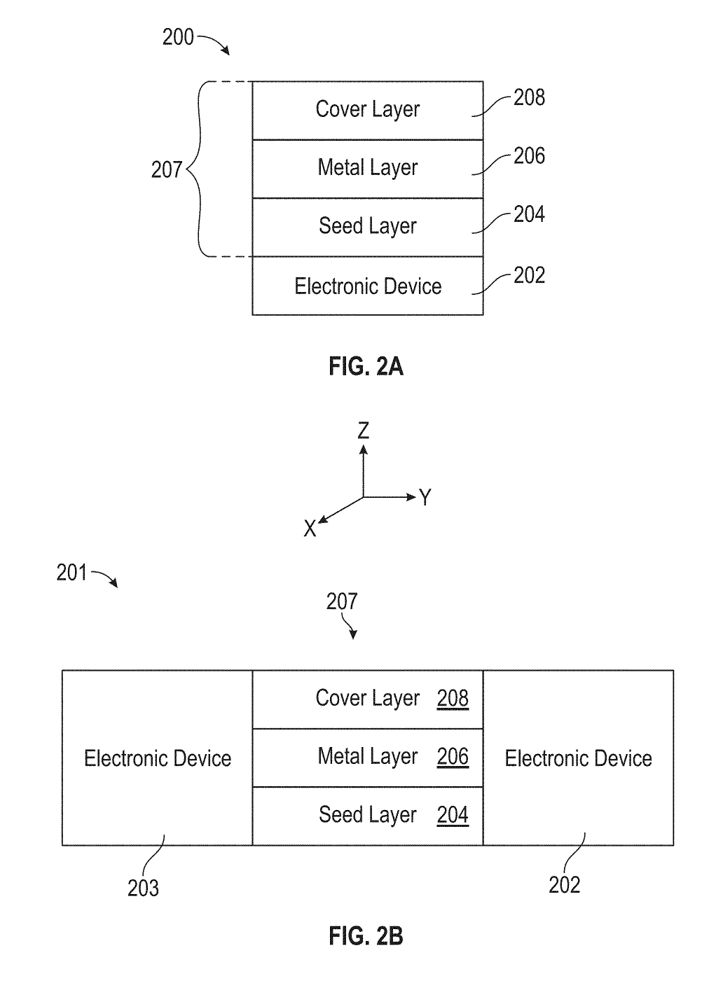

FIG. 2A shows a diagram 200 of an example conformal coating shield 203 that can be deposited on an example surface of an electronic component 202 and/or a surface of a molding compound (not shown) deposited on an electronic component 202, in accordance with example embodiments of the disclosure. In particular, a seed layer 204 may optionally be deposited on the surface of the electronic component 202 and/or a surface of a molding compound (not shown) deposited on an electronic component 202. In one embodiment, the seed layer 204 may be deposited for conformal coating shields 203 that are deposited using a sputtering technique. In one embodiment, the seed layer 204 can include titanium (Ti) and/or tungsten (Tu) material and/or any combination and/or oxides, intermetallics, and/or alloys thereof that are in substantial contact with one another. In another embodiment, the seed layer 204 can have a thickness of approximately 2 nm to approximately 2 micrometers. In one embodiment, the seed layer 204 can be deposited using, for example, sputtering, paste printing, atomic layer deposition (ALD), chemical catalytic deposition from solution, or a variety of different physical vapor deposition (PVD) techniques.

In one embodiment, a shielding layer (for example, a metal shielding layer) 206 can be deposited on the seed layer 204. In one embodiment, the shielding layer (for example, metal shielding layer) 206 can include gold, copper, silver, aluminum, zinc, tin, platinum, and any of the like. In one embodiment, the shielding layer 206 may also be any alloys of such materials. In another embodiment, the shielding layer 206 can have a thickness of approximately 1 micrometer to approximately 20 micrometers, with example thicknesses of approximately 4 micrometers to approximately 20 micrometers. In one embodiment, the shielding layer 206 may be deposited by any suitable mechanism including, but not limited to, metal foil lamination, PVD, chemical vapor deposition (CVD), sputtering, metal paste deposition, combinations thereof, or the like.

In one embodiment, a cover layer 208 can optionally be deposited on the shielding layer 206. In one embodiment, the cover layer 208 can include an inert metal layer, for example, a gold layer and/or a platinum layer. In another embodiment, the cover layer 208 can include a stainless steel layer. In another embodiment, the cover layer 208 can have a thickness of approximately 2 nm to approximately 2 micrometers. In one embodiment, the cover layer 208 can be deposited by any suitable mechanism including, but not limited to, metal foil lamination, PVD, CVD, sputtering, metal paste deposition, combinations thereof, or the like. In one embodiment, the cover layer 208 can serve to protect the shielding layer 206 from environmental exposure, for example, from oxidation.

FIG. 2B further shows a diagram 201 of an example compartmental shield 207 that can be deposited on an example surface of a substrate (for example, a PCB, not shown) and/or a surface of a molding compound (not shown) deposited on an electronic component or a substrate, between at least two electronic components, in accordance with example embodiments of the disclosure. In one embodiment, the compartmental shield 207 can include a seed layer 204, a metal layer 206, and a cover layer 208. Alternatively or additionally, the compartmental shield 207 may only include a single layer, with the conformal coating shield acting as a cover layer instead of cover layer 208. Further, the compartmental shield 207 may only include a metal filled conductive paste, which can be filled in the space between two electronic devices (for example, electronic device 203 and electronic device 205) and then thermally cured at a predetermined temperature and duration.

In the embodiment shown in FIG. 2B, a seed layer 204 may optionally be deposited on the surface of a substrate (for example, a PCB, not shown) and/or a surface of a molding compound (not shown). In one embodiment, the seed layer 204 may be deposited using a sputtering technique. In one embodiment, the seed layer 204 can include titanium (Ti) and/or tungsten (Tu) material and/or any combination and/or oxides, intermetallics, and/or alloys thereof that are in substantial contact with one another. In another embodiment, the seed layer 204 can have a thickness of approximately 2 nm to approximately 2 micrometers. In one embodiment, the seed layer 204 can be deposited using, for example, sputtering, paste printing, atomic layer deposition (ALD), chemical catalytic deposition from solution, or a variety of different physical vapor deposition (PVD) techniques.

In one embodiment, a shielding layer (for example, a metal shielding layer) 206 can be deposited on the seed layer 204. In one embodiment, the shielding layer (for example, the metal shielding layer) 206 can include gold, copper, silver, aluminum, zinc, tin, platinum, and any of the like. In one embodiment, the shielding layer 206 may also be any alloys of such materials. In another embodiment, the shielding layer 206 can have a thickness of approximately 1 micrometer to approximately 20 micrometers, with example thicknesses of approximately 4 micrometers to approximately 20 micrometers. In one embodiment, the shielding layer 206 may be deposited by any suitable mechanism including, but not limited to, metal foil lamination, PVD, chemical vapor deposition (CVD), sputtering, metal paste deposition, combinations thereof, or the like.

In one embodiment, a cover layer 208 can optionally be deposited on the shielding layer 206. In one embodiment, the cover layer 208 can include an inert metal layer, for example, a gold layer and/or a platinum layer. In another embodiment, the cover layer 208 can include a stainless steel layer. In another embodiment, the cover layer 208 can have a thickness of approximately 2 nm to approximately 2 micrometers. In one embodiment, the cover layer 208 can be deposited by any suitable mechanism including, but not limited to, metal foil lamination, PVD, CVD, sputtering, metal paste deposition, combinations thereof, or the like. In one embodiment, the cover layer 208 can serve to protect the shielding layer 206 from environmental exposure, for example, from oxidation.

In one embodiment, the spacing of the electronic devices 205 may be pre-determined to comply with one or more industrial standards. In one embodiment, the height of the electronic components 205 may be predetermined, to conform with one or more processes being executed.

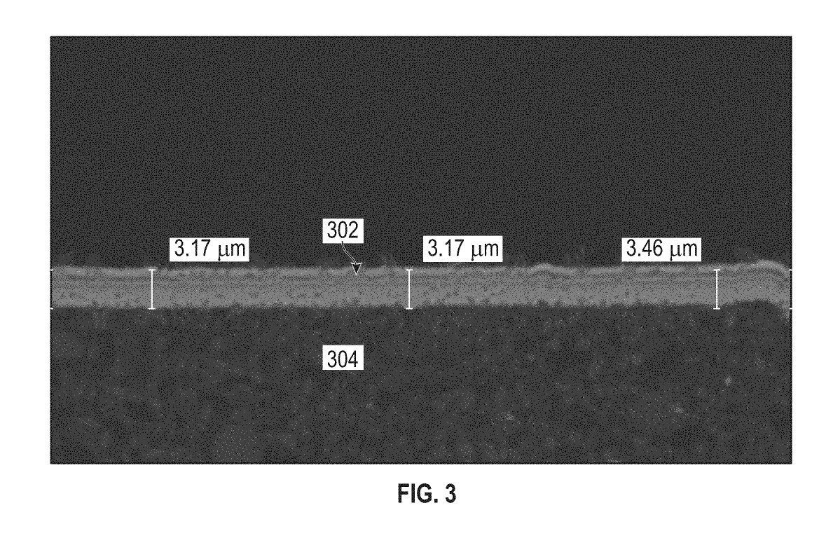

FIG. 3 shows a photograph of an example fabricated conformal coating shield 302 deposited on a molding compound 304, in accordance with example embodiments of the disclosure. In one embodiment, the conformal coating shield 302 can be a conductive adhesive. In one embodiment, the conformal coating shield 302 can include a multilayer. In one embodiment, the lower the resistivity of the conformal coating shield 302, the higher the conductivity of the conformal coating shield 302. In one embodiment, the higher the conductivity and/or the lower the resistivity, the better the conformal coating shield 302 can shield the electronic components and/or the semiconductor package.

In one embodiment, the conformal coating shield 302 can include a conductive adhesive that can be deposited using a spray technique. In one embodiment, the spray technique can include, for example, an atomization spray, an ultrasonic spray, and/or an electrospray technique. In another embodiment, the atomization spray, ultrasonic spray, and/or the electrospray technique can serve to create finer and finer particles that can lead to the fabrication of a more uniform and defect-free conformal coating shield 302.

In one embodiment, the conformal coating shield 302 can additionally be deposited using a dispensing and/or printing technique. For example, the printing technique can include a conventional printing technique. In one embodiment, the printing technique can further include a vacuum printing technique, which can serve to reduce the generation of voids in the shielding layer and/or multilayer. In one embodiment, vacuuming print can be used for filling fine spaces and/or trenches between electronic components on the semiconductor package. In one embodiment, the dispensing technique can include Auger dispensing technique and/or a jet dispensing technique. In one embodiment, the Auger dispensing technique can resemble a drill-type mechanism. In one embodiment, another technique that can be used to deposit a conformal coating shield 302 can include plating. In one embodiment, a conformal coating shield 302 that is deposited using plating can be thicker than one deposited using sputtering.

In one embodiment, for a conformal coating shield 302 deposited using a dispensing and/or printing technique, there may be a post-deposition thermal curing step. optionally be annealed. In one embodiment, the annealing and/or curing can include curing and/or sintering at a temperature range of approximately 75 degrees Centigrade to approximately 200 degrees Centigrade. In one embodiment, the lower the temperature, the less disruptive the heat may be to the components of the semiconductor package (for example, optoelectronics packages including, for example, components including lenses, MEMS, and/or magnets). In another embodiment, for a conformal coating shield 302 deposited using a sputtering technique, there may not be a post curing step.

In one embodiment, the electronic components on the semiconductor package can be disposed in molding material. In one embodiment, the molding material can include an epoxy-based or an underfill material that can provide mechanical stability to the electronic components on semiconductor.

In one embodiment, conformal coating shield 302 can have a thickness of approximately 1 micron to 10 microns, which example thickness of approximately 3 microns to approximately 5 microns. In another embodiment, the thickness of the conformal coating shield 302 can be on the order of approximately 5 nanometers to approximately 1000 nanometers. In one embodiment, the thickness of the conformal coating shield 302 can depend on the frequency range for shielding and/or the material(s) used for shielding. For a copper compartmental and/or conformal coating shielding at electromagnetic radiation at approximately 5 GHz, the conformal coating shield 302 can have a thickness of approximately 2 microns.

In one embodiment, for many electronic components requiring shielding for radiation from a range of approximately 1 GHz and above, approximately 4 micron to approximately 5 microns of a shielding layer may provide adequate shielding.

In one embodiment, for conformal coating shield 302 that are deposited using sputtering, a seed layer may need to be deposited first for adhesion. In one embodiment, a cover layer can be deposited on a shielding layer. For example, in the case of some metal materials, the cover can serve to protect the shielding layer from rusting. For example, the conformal coating shield 302 can include a stainless steel material.

In one embodiment, a seed layer for the conformal coating shield 302 can include titanium. In another embodiment, the thickness of the seed layer can be approximately 1 micron to approximately 0.1 micron in thickness. In one embodiment, the seed layer can provide for adhesion of the conformal coating shield 302 to the underlying electronic component(s) and/or semiconductor package and/or molding layer 304. In one embodiment, sputtered titanium can adhere to the molding layer 304 and other polymers.

In one embodiment, the shielding material can include a conductive paste or a conductive polymer. In another embodiment, the shielding material can include an adhesive property. In one embodiment, the adhesive property can be reduced by the application of a thermal curing process. In one embodiment, the shielding material can include a metal that uses silver nanoparticles.

In one embodiment, for conformal coating shield 302 including conductive pastes and/or inks, the molding layer's 304 surface can be plasma treated prior to the application of the conductive paste and/or ink. In one embodiment, the plasma treatment can serve to roughen the molding layer's 304 surface, thereby allowing for better adhesion.

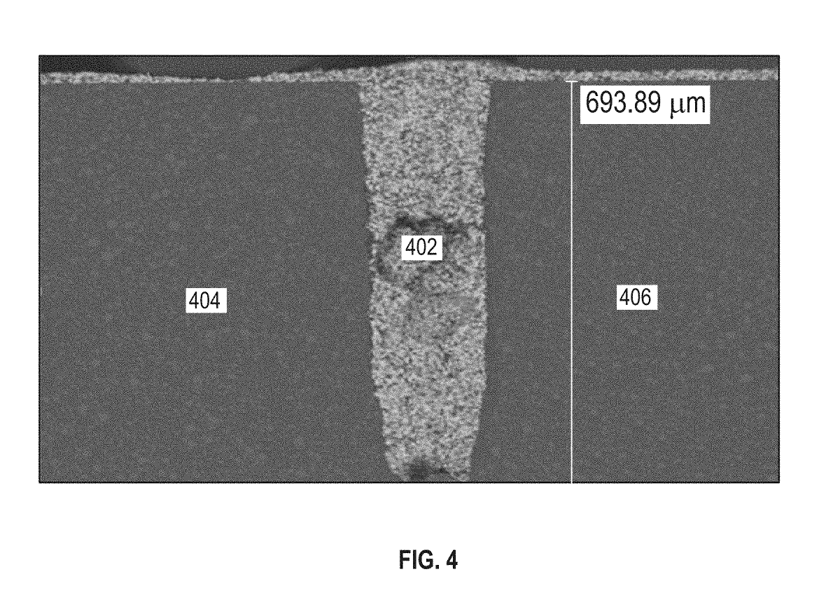

FIG. 4 shows a photograph of an example fabricated compartmental shield 402 deposited in a trench between two electronic components 404 and 406, in accordance with example embodiments of the disclosure. In one embodiment, the compartmental shield 402 can include a conductive adhesive that can be deposited using a spray technique. In one embodiment, the spray technique can include, for example, an atomization spray, an ultrasonic spray, and/or an electrospray technique. In another embodiment, the atomization spray, ultrasonic spray, and/or the electrospray technique can serve to create finer and finer particles that can lead to the fabrication of a more uniform and defect-free compartmental shield 402.

In one embodiment, the compartmental shield 402 can additionally be deposited using a dispensing and/or printing technique. For example, the printing technique can include a conventional printing technique. In one embodiment, the printing technique can further include a vacuum printing technique, which can serve to reduce the generation of voids in the compartmental shield 402. In one embodiment, vacuuming print can be used for filling fine spaces and/or trenches between electronic components on the semiconductor package. In one embodiment, the dispensing technique can include Auger dispensing technique and/or a jet dispensing technique. In one embodiment, the Auger dispensing technique can resemble a drill-type mechanism. In one embodiment, another technique that can be used to deposit a compartmental shield 402 can include plating. In one embodiment, a compartmental shield 402 that is deposited using plating can be thicker than one deposited using sputtering.

In one embodiment, for a compartmental shield 402 deposited using a dispensing and/or printing technique, there may be a post-deposition thermal curing step. optionally be annealed. In one embodiment, the annealing and/or curing can include curing and/or sintering at a temperature range of approximately 75 degrees Centigrade to approximately 200 degrees Centigrade. In one embodiment, the lower the temperature, the less disruptive the heat may be to the components of the semiconductor package (for example, optoelectronics packages including, for example, components including lenses, MEMS, and/or magnets). In another embodiment, for a compartmental shield 402 deposited using a sputtering technique, there may not be a post curing step.

In one embodiment, the electronic components on the semiconductor package can be disposed in molding material. In one embodiment, the molding material can include an epoxy-based or an underfill material that can provide mechanical stability to the electronic components on semiconductor.

In one embodiment, the a layer and/or multilayer of shielding can having a thickness of approximately 1 micron to 10 microns, which example thickness of approximately 3 microns to approximately 5 microns. In another embodiment, the thickness of the shielding layer and/or a given layer of the multilayer can be on the order of approximately 5 nanometers to approximately 1000 nanometers. In one embodiment, the thickness of the compartmental shield 402 can depend on the frequency range for shielding and/or the material(s) used for shielding. For a copper compartmental and/or conformal coating shielding at electromagnetic radiation at approximately 5 GHz, the shielding layer can have a thickness of approximately 2 microns.

In one embodiment, for many electronic components requiring shielding for radiation from a range of approximately 1 GHz and above, approximately 4 micron to approximately 5 microns of a shielding layer may provide adequate shielding.

In one embodiment, for shielding layers and/or multilayers that are deposited using sputtering, a seed layer may need to be deposited first for adhesion. In one embodiment, a cover layer can be deposited on a shielding layer. For example, in the case of some metal materials, the cover can serve to protect the shielding layer from rusting. For example, the shielding layer can include a stainless steel material.

In one embodiment, a seed layer for the compartmental shield 402 can include titanium. In another embodiment, the thickness of the seed layer can be approximately 1 micron to approximately 0.1 micron in thickness. In one embodiment, the seed layer can provide for adhesion of the compartmental shield 402 to the underlying electronic component(s) and/or semiconductor package. In one embodiment, sputtered titanium can adhere to the molding compounds and other polymers.

In one embodiment, the shielding material can include a conductive paste or a conductive polymer. In another embodiment, the shielding material can include an adhesive property. In one embodiment, the adhesive property can be reduced by the application of a thermal curing process. In one embodiment, the shielding material can include a metal that uses silver nanoparticles.

In one embodiment, for compartmental shield 402 including conductive pastes and/or inks, the molding compound's surface can be plasma treated prior to the application of the conductive paste and/or ink. In one embodiment, the plasma treatment can serve to roughen the molding compound's surface, thereby allowing for better adhesion.

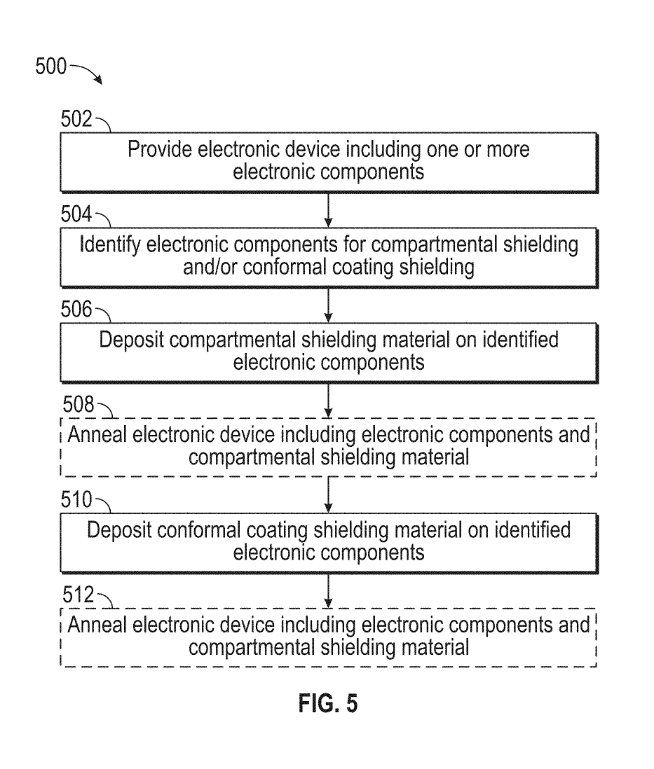

FIG. 5 shows an example processing flow diagram for the fabrication of the compartmental and/or conformal coating shields, in accordance with example embodiments of the disclosure.

In block 502, a portion of a semiconductor package can be provided, a portion of the semiconductor package including one or more electronic components. In one embodiment, the shielding systems, methods, and apparatus disclosed herein can be used in connection with electronic components, for example, electronic components on a semiconductor package. In one embodiment, the electronic components can include built-in mobile camera modules. In another embodiment, the systems, methods, and apparatus disclosed herein can be used in connection with semiconductor packages, for example, with optoelectronics packages. In such optoelectronics packages, the light from a diode may be projected onto a scene and then the light that that is reflected back can be collected and processed by one or more processors to generate an image. Other non-limiting examples of electronic components that can be used in connection with the disclosure include Central Processing Units (CPUs), logic chips, memory chips, LTE chips, Bluetooth chips, Wi-Fi chips, photodetectors, and/or sensors.

In one embodiment, semiconductor packages may include different portions associated one or more electronic components of the semiconductor package where electromagnetic (for example, radio-frequency, RF) shielding at predetermined frequencies ranges may be needed. In one embodiment, a can (for example, a metallic can) can be used to enclose various portions of the semiconductor package to provide shielding for one or more electronic components (for example, one or more detectors and/or optoelectronic packages and/or devices) on the semiconductor package.

In one embodiment, one or more electronic components on a semiconductor package may emit electromagnetic radiation at various frequencies. For example, low frequency radiation (below approximately 1 GHz) can be emitted by switches, motors, power supplies, and transformers. As another example, higher frequency (for example, approximately 1 GHz to approximately 10 GHz frequencies) radiation can be emitted by components including CPUs or logic chips, memory chips, LTE chips, Bluetooth chips, Wi-Fi chips. Such radiation may need to be attenuated to reduce interference with electronic components that are exposed to the radiation.

In block 504, one or more electronic components can be identified for compartmental shielding and/or conformal coating shielding. In one embodiment, there may be approximately hundreds of electrical components on a given semiconductor package (for example, a semiconductor package including an optoelectronic package and/or device), but not every electronic component may need to be shielded. For example, there may be a predetermined number of electronic components (for example, three to four electronic components) that may need to be shielded from electromagnetic radiation at predetermined frequencies.

In block 506, compartmental shielding material can be deposited on identified electronic components. In one embodiment, the materials can include materials can be used for sputtering (for example, titanium as a seed layer, copper as a shielding layer, and a stainless steel layer as the cove. Alternatively or additionally, CuNiFeZn and/or other ferrites can be used as a shielding layer for lower-frequency applications. In one embodiment, metals can be plated (using various plating chemistries). In one embodiment, sinterable nanoparticles (for example, silver, copper, and other metal nanoparticles) can be used as the shielding layer. In one embodiment, non-sinterable pastes and/or inks (for example, non-sinterable pastes and/or inks containing metals such as Ag, Cu, Ni, Fe) in an epoxy, acrylic, or other polymer formulation can be used for the shielding layer. In one embodiment, intermetallic compound-forming materials (such as SnBiCu pastes), and/or conductive particles (such as fibers, flakes, nanoparticles, graphite, and the like) can be used for the shielding layer.

In various embodiments a variety of techniques including sputtering techniques, and spraying techniques (including atomization, electrospray, and/or ultrasonic spraying techniques) can be used to deposit the shielding material. In another embodiment, plating (including, for example, electrolytic and electroless plating), printing (including, for example, vacuum printing and/or conventional printing), and/or dispensing techniques (including, for example, Auger and/or jet dispensing) techniques can be used to deposit the shielding material.

In one embodiment, the material(s) used for conformal coating shielding and/or compartmental shielding can be selected to provide shielding at approximately 2.4 GHz to approximately 5 GHz frequency range. In another embodiment, the material(s) used for conformal coating shielding and/or compartmental shielding can be selected to provide shielding at comparatively lower frequency ranges (for example, shielding from radiation having a frequency in the MHz range).

In one embodiment, for comparatively lower frequency shielding, the shielding material for conformal coating shielding and/or compartmental shielding can be selected based at least in part on the shielding material's magnetic permeability. In one embodiment, iron can be used for the shielding material. In another embodiment, the resistivity of the shielding material may not as important of a consideration as the magnetic permeability in the shielding properties of the shielding layer and/or multilayer for comparatively lower frequency applications. In one embodiment, the lower-frequency conformal coating shielding and/or compartmental shielding can reduce RF interference from power lines or similar structures in the environment of the shielded electronic components and/or the shielded semiconductor package.

In block 508, the portion of the semiconductor package including the electronic components and the compartmental shielding material can optionally be annealed. In one embodiment, the annealing and/or curing can include curing and/or sintering at a temperature range of approximately 75 degrees Centigrade to approximately 200 degrees Centigrade. In one embodiment, the lower the temperature, the less disruptive the heat may be to the components of the semiconductor package (for example, optoelectronics packages including, for example, components including lenses, MEMS, and/or magnets).

In block 510, conformal coating shielding material can be deposited on the identified electronic components. In one embodiment, the materials can include materials can be used for sputtering (for example, titanium as a seed layer, copper as a shielding layer, and a stainless steel layer as the cove. Alternatively or additionally, CuNiFeZn and/or other ferrites can be used as a shielding layer for lower-frequency applications. In one embodiment, metals can be plated (using various plating chemistries). In one embodiment, sinterable nanoparticles (for example, silver, copper, and other metal nanoparticles) can be used as the shielding layer. In one embodiment, non-sinterable pastes and/or inks (for example, non-sinterable pastes and/or inks containing metals such as Ag, Cu, Ni, Fe) in an epoxy, acrylic, or other polymer formulation can be used for the shielding layer. In one embodiment, intermetallic compound-forming materials (such as SnBiCu pastes), and/or conductive particles (such as fibers, flakes, nanoparticles, graphite, and the like) can be used for the shielding layer. In various embodiments a variety of techniques including sputtering techniques, and spraying techniques (including atomization, electrospray, and/or ultrasonic spraying techniques) can be used to deposit the shielding material. In another embodiment, plating (including, for example, electrolytic and electroless plating), printing (including, for example, vacuum printing and/or conventional printing), and/or dispense techniques (including, for example, Auger and/or jet dispensing) techniques can be used.

In one embodiment, the material(s) used for conformal coating shielding and/or compartmental shielding can be selected to provide shielding at approximately 2.4 to approximately 5 GHz frequency range. In another embodiment, the material(s) used for conformal coating shielding and/or compartmental shielding can be selected to provide shielding at comparatively lower frequency ranges (for example, shielding from radiation having a frequency in the MHz range).

In one embodiment, for comparatively lower frequency shielding, the shielding material for conformal coating shielding and/or compartmental shielding can be selected based at least in part on the shielding material's magnetic permeability. In one embodiment, iron can be used for the shielding material. In another embodiment, the resistivity of the shielding material may not as important of a consideration as the magnetic permeability in the shielding properties of the shielding layer and/or multilayer for comparatively lower frequency applications. In one embodiment, the lower-frequency conformal coating shielding and/or compartmental shielding can reduce RF interference from power lines or similar structures in the environment of the shielded electronic components and/or the shielded semiconductor package.

In block 512, the portion of the semiconductor package including the electronic components and the conformal coating shielding material can optionally be annealed. In one embodiment, the annealing and/or curing can include curing and/or sintering at a temperature range of approximately 75 degrees Centigrade to approximately 200 degrees Centigrade. In one embodiment, the lower the temperature, the less disruptive the heat may be to the components of the semiconductor package (for example, optoelectronics packages including, for example, components including lenses, MEMS, and/or magnets).

In various embodiments the semiconductor package described herein may have one or more electronic components disposed thereon. The electronic components may include, but not be limited to, optoelectronic devices, integrated circuits, surface mount devices, active devices, passive devices, diodes, transistors, connectors, resistors, inductors, capacitors, microelectromechanical systems (MEMSs), combinations thereof, or the like. The electronic components may be electrically and mechanically coupled to the semiconductor package substrate via any suitable mechanism, such as metal pillars (e.g., copper pillars), flip chip bumps, solder bumps, any type of low-lead or lead-free solder bumps, tin-copper bumps, wire bonds, wedge bonds, controlled collapse chip connects (C4), anisotropic conductive film (ACF), nonconductive film (NCF), combinations thereof, or the like.

In one embodiment, ground pads on the semiconductor package may be extensions of a ground plane that may be, in example embodiments, a build-up layer (for example, a build-up layer with interconnects) within the semiconductor package substrate. When the semiconductor package is in operation, the ground plane may be shorted to ground, such as on a printed circuit board (PCB) on which the semiconductor package is disposed. The ground plane may be electrically connected, in example embodiments, to one or more ground pads. The ground pads may include one or more pads and/or interconnect traces (e.g., surface wiring traces) on the top surface of the semiconductor package.

In various embodiments, the substrate associated with the semiconductor package may be of any suitable size and/or shape. For example, the substrate associated with the semiconductor package, in example embodiments, may be a rectangular panel. In example embodiments, the substrate associated with the semiconductor package may be fabricated of any suitable material, including polymer material, ceramic material, plastics, composite materials, glass, epoxy laminates of fiberglass sheets, FR-4 materials, FR-5 materials, combinations thereof, or the like. In one embodiment, the substrate associated with the semiconductor package may have a core layer and any number of interconnect build-up layers on either side of a core layer. The core and/or the interconnect build-up layers may be any variety of the aforementioned materials and, in some example embodiments, may not be constructed of the same material types. It will be appreciated that the build-up layers may be fabricated in any suitable fashion. For example a first layer of build-up interconnect may include providing a package substrate core, with or without through holes formed therein. Dielectric laminate material may be laminated on the semiconductor substrate core material. Vias and/or trenches may be patterned in the build-up layer using any suitable mechanism, including photolithography, plasma etch, laser ablation, wet etch, combinations thereof, or the like. The vias and trenches may be defined by vertical and horizontal metal traces, respectively within the build-up layer. The vias and trenches may then be filled with metal, such as by electroless metal plating, electrolytic metal plating, physical vapor deposition, combinations thereof, or the like. Excess metal may be removed by any suitable mechanism, such as etch, clean, polish, and/or chemical mechanical polish (CMP), combinations thereof, or the like. Subsequent build-up layers (e.g., higher levels of build-up layers) on either side of the core may be formed by the same aforementioned processes.

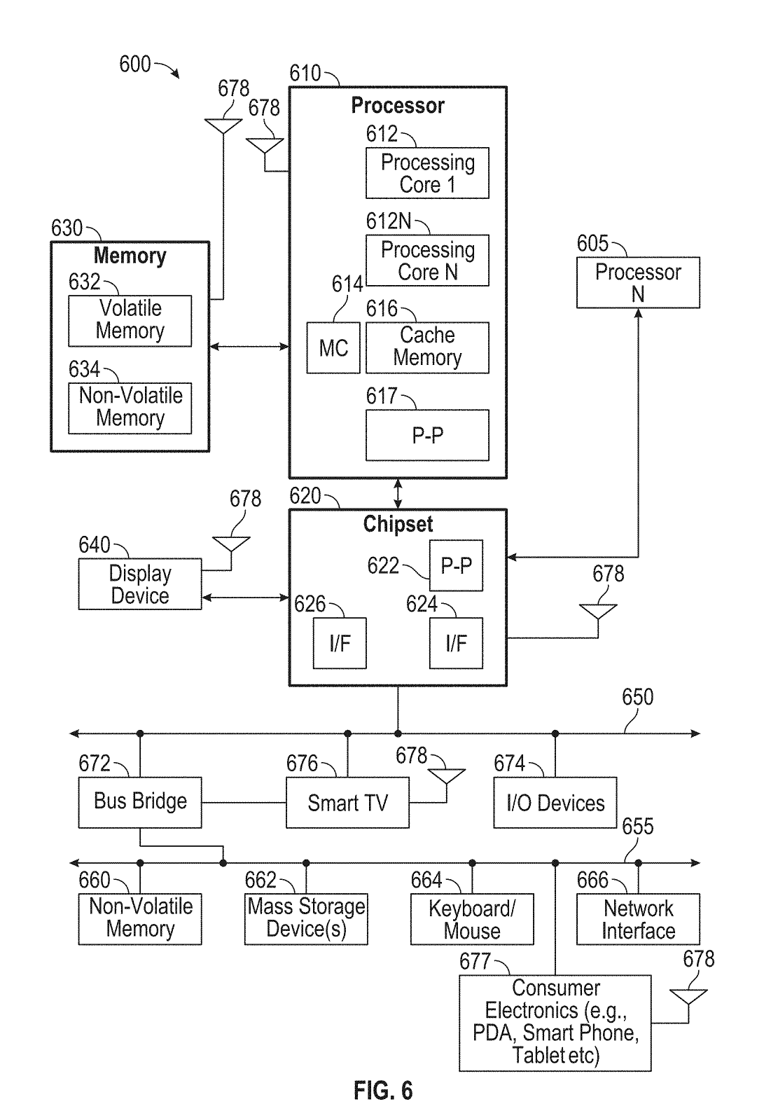

FIG. 6 depicts an example of a system 600 according to one or more embodiments of the disclosure. In one embodiment, the shielding layers (for example, the conformal coating shielding layer and/or the compartmental shielding layer disclosed herein) can be used to provide electromagnetic (for example, radio frequency, RF) shielding for one or more devices shown and described in FIG. 6. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 600 can include a system on a chip (SOC) system.

In one embodiment, system 600 includes multiple processors including processor 610 and processor N 605, where processor N 605 has logic similar or identical to the logic of processor 610. In one embodiment, processor 610 has one or more processing cores (represented here by processing core 1 612 and processing core N 612N, where 612N represents the Nth processor core inside processor 610, where N is a positive integer). More processing cores can be present (but not depicted in the diagram of FIG. 6). In some embodiments, processing core 612 includes, but is not limited to, pre-fetch logic to fetch instructions, decode logic to decode the instructions, execution logic to execute instructions, a combination thereof, or the like. In some embodiments, processor 610 has a cache memory 616 to cache instructions and/or data for system 600. Cache memory 616 may be organized into a hierarchical structure including one or more levels of cache memory.

In some embodiments, processor 610 includes a memory controller (MC) 614, which is configured to perform functions that enable the processor 610 to access and communicate with memory 630 that includes a volatile memory 632 and/or a non-volatile memory 634. In some embodiments, processor 610 can be coupled with memory 630 and chipset 620. Processor 610 may also be coupled to a wireless antenna 678 to communicate with any device configured to transmit and/or receive wireless signals. In one embodiment, the wireless antenna antenna 678 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory device 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interface 617 and P-P interface 622. Chipset 620 enables processor 610 to connect to other elements in system 600. In some embodiments of the disclosure, P-P interface 617 and P-P interface 622 can operate in accordance with a PtP communication protocol, such as the Intel® QuickPath Interconnect (QPI) or the like. In other embodiments, a different interconnect may be used.

In some embodiments, chipset 620 can be configured to communicate with processor 610, the processor N 605, display device 640, and other devices 672, 676, 674, 660, 662, 664, 666, 677, etc. Chipset 620 may also be coupled to the wireless antenna 678 to communicate with any device configured to transmit and/or receive wireless signals.

Chipset 620 connects to display device 640 via interface 626. Display 640 may be, for example, a liquid crystal display (LCD), a plasma display, cathode ray tube (CRT) display, or any other form of visual display device. In some embodiments of the disclosure, processor 610 and chipset 620 are integrated into a single SOC. In addition, chipset 620 connects to bus 650 and/or bus 655 that interconnect various elements 674, 660, 662, 664, and 666. Bus 650 and bus 655 may be interconnected via a bus bridge 672. In one embodiment, chipset 620 couples with a non-volatile memory 660, a mass storage device(s) 662, a keyboard/mouse 664, and a network interface 666 via interface 624 and/or 604, smart TV 676, consumer electronics 677, etc.

In one embodiment, mass storage device(s) 662 can include, but not be limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 7 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 or selected elements thereof can be incorporated into processor core 612.

It is noted that the system 600 described herein may be any suitable type of microelectronics packaging and configurations thereof, including, for example, system in a package (SiP), system on a package (SOP), package on package (PoP), interposer package, 3D stacked package, etc. Further, any suitable type of microelectronic components may be provided in the semiconductor packages, as described herein. For example, microcontrollers, microprocessors, baseband processors, digital signal processors, memory dies, field gate arrays, logic gate dies, passive component dies, MEMSs, surface mount devices, application specific integrated circuits, baseband processors, amplifiers, filters, combinations thereof, or the like may be packaged in the semiconductor packages, as disclosed herein. The semiconductor packages (for example, the semiconductor packages described in connection with any of FIGS. 1-6), as disclosed herein, may be provided in any variety of electronic device including consumer, industrial, military, communications, infrastructural, and/or other electronic devices.

In various embodiments, the devices, as described herein, may be used in connection with one or more processors. The one or more processors may include, without limitation, a central processing unit (CPU), a digital signal processor(s) (DSP), a reduced instruction set computer (RISC), a complex instruction set computer (CISC), a microprocessor, a microcontroller, a field programmable gate array (FPGA), or any combination thereof. The processors may also include one or more application specific integrated circuits (ASICs) or application specific standard products (ASSPs) for handling specific data processing functions or tasks. In certain embodiments, the processors may be based on an Intel® Architecture system and the one or more processors and any chipset included in an electronic device may be from a family of Intel® processors and chipsets, such as the Intel® Atom® processor(s) family or Intel-64 processors (for example, Sandy Bridge®, Ivy Bridge®, Haswell®, Broadwell®, Skylake®, etc.).

Additionally or alternatively, the devices, as described herein, may be used in connection with one or more additional memory chips. The memory may include one or more volatile and/or non-volatile memory devices including, but not limited to, magnetic storage devices, read-only memory (ROM), random access memory (RAM), dynamic RAM (DRAM), static RAM (SRAM), synchronous dynamic RAM (SDRAM), double data rate (DDR) SDRAM (DDR-SDRAM), RAM-BUS DRAM (RDRAM), flash memory devices, electrically erasable programmable read-only memory (EEPROM), non-volatile RAM (NVRAM), universal serial bus (USB) removable memory, or combinations thereof.

In example embodiments, the electronic device in which the disclosed devices are used and/or provided may be a computing device. Such a computing device may house one or more boards on which the devices may be disposed. The board may include a number of components including, but not limited to, a processor and/or at least one communication chip. The processor may be physically and electrically connected to the board through, for example, electrical connections of the devices. The computing device may further include a plurality of communication chips. For instance, a first communication chip may be dedicated to shorter range wireless communications such as Wi-Fi and Bluetooth, and a second communication chip may be dedicated to longer range wireless communications such as GPS, EDGE, GPRS, CDMA, WiMAX, LTE, EV-DO, and others. In various example embodiments, the computing device may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, a digital video recorder, combinations thereof, or the like. In further example embodiments, the computing device may be any other electronic device that processes data.

According to example embodiments of the disclosure there may be a method. The method may comprise: providing at least a portion of a semiconductor package including a first electronic component and a second electronic component attached to a board having a first grounding pad between the first electronic component and the second electronic component; applying compartmental shielding material to at least a portion of the grounding pad; applying heat to the compartmental shielding material at a first temperature for a first duration; applying a conformal coating shielding material on at least a portion of the first electronic component and the second electronic component, the conformal coating shield being in contact with at least one of a second grounding pad on the board or the compartmental shielding material; and applying heat to the conformal coating shielding material at a second temperature for a second duration.

Implementation may include one or more of the following features. The two or more electronic components may comprise two or more of a central processing unit (CPU), a logic circuit, a memory circuit, a Long-Term Evolution (LTE) circuitry, a Bluetooth circuitry, a Wi-Fi circuitry, a photodetector, a photodiode, a laser diode, a microelectromechanical systems (MEMS) device, or a sensor. Applying the compartmental shielding material may comprise applying the compartmental shielding material using a spraying technique, a plating technique, a printing technique, or a dispensing technique. Applying the conformal coating shielding material may comprise applying the conformal coating shielding material using a spraying technique, a plating technique, a printing technique, or a dispensing technique. Applying the compartmental shielding material may comprise applying the compartmental shielding material using a plating technique, wherein the plating technique comprises an electrolytic plating technique or an electroless plating technique. Applying the conformal coating shielding material may comprise applying the conformal coating material using a plating technique, wherein the plating technique comprises an electrolytic plating technique or an electroless plating technique. Applying the compartmental shielding material may comprise applying the compartmental shielding material using a spraying technique, wherein the spraying technique comprises an atomization technique, an electrospray technique, or an ultrasonic technique. Applying the conformal coating shielding material may comprise applying the conformal coating shielding material using a spraying technique, wherein the spraying technique comprises an atomization technique, an electrospray technique, or an ultrasonic technique. Applying the compartmental shielding material may comprise applying the compartmental shielding material using a printing technique, wherein the printing technique comprises a vacuum printing technique. Applying the conformal coating shielding material may comprise applying the conformal coating shielding material using a printing technique, wherein the printing technique comprises a vacuum printing technique. Applying the compartmental shielding material may comprise applying the compartmental shielding material using a dispensing technique, wherein the dispensing technique comprises an Auger dispensing technique or a jet dispensing technique. Applying the conformal coating shielding material may comprise applying the conformal coating shielding material using a dispensing technique, wherein the dispensing technique comprises an Auger dispensing technique or a jet dispensing technique. The application of heat may comprise photonic curing. The compartmental shielding material may comprise sintering nanoparticles, non-sintering pastes, non-sintering inks, intermetallic compound forming, conductive particles. The sintering nanoparticles comprise silver or copper. The non-sintering pastes or the non-sintering inks may comprise a metal. The non-sintering pastes or the non-sintering inks comprise epoxy acrylic adhesive system or other polymer systems. The intermetallic compound-forming may comprise a SnBiCu paste. The conductive particles may include fibers, flakes, nanoparticles, or graphite.

According to example embodiments of the disclosure, there may be semiconductor package. The package may comprise: a compartmental shielding material that is applied to at least a portion of one or more grounding pads of a semiconductor package, the compartmental shielding material applied between at least two electronic devices disposed on the semiconductor package; wherein heat is applied to the compartmental shielding material at a first temperature for a first duration; a conformal coating shielding material that is applied to at least a portion of the one or more electronic components of the device, the conformal coating shield being in contact with at least one of the one or more grounding pads or the compartmental shielding material; and wherein heat is applied to the conformal coating shielding material at a second temperature for a second duration.

Implementation may include one or more of the following features. The compartmental shielding material or the conformal coating shielding material may comprise sintering nanoparticles, non-sintering pastes, non-sintering inks, intermetallic compound forming, conductive particles. The sintering nanoparticles may comprise silver or copper. The non-sintering pastes or the non-sintering inks may comprise a metal. The non-sintering pastes or the non-sintering inks may comprise epoxy acrylic adhesive system or other polymer systems. The conductive particles may include fibers, flakes, nanoparticles, or graphite.

According to example embodiments of the disclosure, there may be an electronic device. The electronic device may comprise: a semiconductor package, comprising: a compartmental shielding material that is applied to at least a portion of one or more grounding pads of a semiconductor package, the compartmental shielding material applied between at least two electronic devices disposed on the semiconductor package; wherein heat is applied to the compartmental shielding material at a first temperature for a first duration; a conformal coating shielding material that is applied to at least a portion of the one or more electronic components of the device, the conformal coating shield being in contact with at least one of the one or more grounding pads or the compartmental shielding material; and wherein heat is applied to the conformal coating shielding material at a second temperature for a second duration.

Implementation may include one or more of the following features. The compartmental shielding material or the conformal coating shielding material may comprise sintering nanoparticles, non-sintering pastes, non-sintering inks, intermetallic compound forming, conductive particles. The sintering nanoparticles may comprise silver or copper. The non-sintering pastes or the non-sintering inks may comprise a metal. The non-sintering pastes or the non-sintering inks may comprise epoxy acrylic adhesive system or other polymer systems. The conductive particles may include fibers, flakes, nanoparticles, or graphite.

Various features, aspects, and embodiments have been described herein. The features, aspects, and embodiments are susceptible to combination with one another as well as to variation and modification, as will be understood by those having skill in the art. The present disclosure should, therefore, be considered to encompass such combinations, variations, and modifications.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Other modifications, variations, and alternatives are also possible. Accordingly, the claims are intended to cover all such equivalents.

While the disclosure includes various embodiments, including at least a best mode, it is to be understood that many alternatives, modifications, and variations will be apparent to those skilled in the art in light of the foregoing description. Accordingly, the disclosure is intended to embrace all such alternatives, modifications, and variations, which fall within the scope of the included claims. All matters disclosed herein or shown in the accompanying drawings are to be interpreted in an illustrative and non-limiting sense.

This written description uses examples to disclose certain embodiments of the disclosure, including the best mode, and also to enable any person skilled in the art to practice certain embodiments of the disclosure, including making and using any apparatus, devices or systems and performing any incorporated methods and processes. The patentable scope of certain embodiments of the invention is defined in the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

1. A method comprising:
providing at least a portion of a semiconductor package including a first electronic component and a second electronic component attached to a board having a first grounding pad between the first electronic component and the second electronic component;
applying compartmental shielding material to at least a portion of the grounding pad;
applying heat to the compartmental shielding material at a first temperature for a first duration;
applying a conformal coating shielding material on at least a portion of the first electronic component and the second electronic component, the conformal coating shield being in contact with at least one of a second grounding pad on the board or the compartmental shielding material; and
applying heat to the conformal coating shielding material at a second temperature for a second duration.

2. The method of claim 1, wherein the first electronic component or the second electronic component comprise a central processing unit (CPU), a logic circuit, a memory circuit, a Long-Term Evolution (LTE) circuitry, a Bluetooth circuitry, a Wi-Fi circuitry, a photodetector, a photodiode, a laser diode, a microelectromechanical systems (MEMS) device, or a sensor.

3. The method of claim 1, wherein applying the compartmental shielding material comprises applying the compartmental shielding material using a spraying technique, a plating technique, a printing technique, or a dispensing technique.

4. The method of claim 1, wherein applying the conformal coating shielding material comprises applying the conformal coating shielding material using a spraying technique, a plating technique, a printing technique, or a dispensing technique.

5. The method of claim 1, wherein applying the compartmental shielding material comprises applying the compartmental shielding material using a plating technique, wherein the plating technique comprises an electrolytic plating technique or an electroless plating technique.

6. The method of claim 1, wherein applying the conformal coating shielding material comprises applying the conformal coating material using a plating technique, wherein the plating technique comprises an electrolytic plating technique or an electroless plating technique.

7. The method of claim 1, wherein applying the compartmental shielding material comprises applying the compartmental shielding material using a spraying technique, wherein the spraying technique comprises an atomization technique, an electrospray technique, or an ultrasonic technique.

8. The method of claim 1, wherein applying the conformal coating shielding material comprises applying the conformal coating shielding material using a spraying technique, wherein the spraying technique comprises an atomization technique, an electrospray technique, or an ultrasonic technique.

9. The method of claim 1, wherein applying the compartmental shielding material comprises applying the compartmental shielding material using a printing technique, wherein the printing technique comprises a vacuum printing technique.

10. The method of claim 1, wherein applying the conformal coating shielding material comprises applying the conformal coating shielding material using a printing technique, wherein the printing technique comprises a vacuum printing technique.

11. The method of claim 1, wherein applying the compartmental shielding material comprises applying the compartmental shielding material using a dispensing technique, wherein the dispensing technique comprises an Auger dispensing technique or a jet dispensing technique.

12. The method of claim 1, wherein applying the conformal coating shielding material comprises applying the conformal coating shielding material using a dispensing technique, wherein the dispensing technique comprises an Auger dispensing technique or a jet dispensing technique.

13. The method of claim 1, wherein the compartmental shielding material comprises sintering nanoparticles, non-sintering pastes, non-sintering inks, intermetallic compound forming, conductive particles.

14. The method of claim 13, wherein the sintering nanoparticles comprise silver or copper.

15. The method of claim 13, wherein the non-sintering pastes or the non-sintering inks comprise epoxy acrylic adhesive system or a polymer systems.

16. The method of claim 13, wherein the conductive particles include fibers, flakes, nanoparticles, or graphite.

17. A semiconductor package, comprising:
a substrate including a first electronic component of a first electronic device and a second electronic component of a second electronic device, and a first grounding pad between the first electronic component and the second electronic component;
a compartmental shielding material disposed on at least a portion of the first grounding pads, the compartmental shielding material applied between the first electronic device and the second electronic device;
a conformal coating shielding material disposed on at least a portion of the first electronic component and the second electronic component, the conformal coating shield being in contact with the grounding pad or the compartmental shielding material.

18. The semiconductor package of claim 17, wherein the compartmental shielding material or the conformal coating shielding material comprises sintering nanoparticles, non-sintering pastes, non-sintering inks, intermetallic compound forming, conductive particles.

19. The semiconductor package of claim 18, wherein the sintering nanoparticles comprise silver or copper.

20. The semiconductor package of claim 18, wherein the non-sintering pastes or the non-sintering inks comprise a metal.

21. The semiconductor package of claim 18, wherein the non-sintering pastes or the non-sintering inks comprise epoxy acrylic adhesive system or other polymer systems.

22. The semiconductor package of claim 18, wherein the conductive particles include fibers, flakes, nanoparticles, or graphite.

23. A device, comprising:
a substrate including a first electronic component and a second electronic component, and a first grounding pad between the first electronic component and the second electronic component;
a compartmental shielding material disposed on at least a portion of the first grounding pads, the compartmental shielding material applied between the first electronic component and the second electronic component;
a conformal coating shielding material disposed on at least a portion of the first electronic component and the second electronic component, the conformal coating shield being in contact with the grounding pad or the compartmental shielding material.

24. The device of claim 23, wherein the compartmental shielding material or the conformal coating shielding material comprises sintering nanoparticles, non-sintering pastes, non-sintering inks, intermetallic compound forming, conductive particles.

25. The method of claim 23, wherein the first electronic component or the second electronic component comprise a central processing unit (CPU), a logic circuit, a memory circuit, a Long-Term Evolution (LTE) circuitry, a Bluetooth circuitry, a Wi-Fi circuitry, a photodetector, a photodiode, a laser diode, a microelectromechanical systems (MEMS) device, or a sensor.
